(19) United States
(12) Patent Application Publication
(10) Pub. No.: US 2007/0064379 A1
(43) Pub. Date: Mar. 22, 2007

(54) DISPLAY APPARATUS

(76) Inventor: Jong-hwa Shin, Yongin-si (KR)

Correspondence Address: STANZIONE & KIM, LLP, 919 18TH STREET, N.W., SUITE 440, WASHINGTON, DC, 20006, US

(21) Appl. No.: 11/533,480

(22) Filed: Sep. 20, 2006

(30) Foreign Application Priority Data
Sep. 21, 2005 (KR) 2005-87664

(51) Int. Cl. G06F 1/16; H05K 7/00; H05K 5/00

(52) U.S. Cl. 361/681

(57) ABSTRACT

A display device including a display main body to display an image thereon and a base member, the display device further including a lifting unit which includes a guide frame standing on the base member and a lifting member coupled with the guide frame to move with the display main body, a pivoting unit which is provided between the display main body and the lifting member and supports the display member to pivot around a rotating axis in clockwise and counterclockwise directions, and a locking unit which includes a moving member to move with a pivoting operation of the display main body and a locking projection provided on the guide frame to limit movement of the moving member to prevent the pivoting operation of the display main body when the lifting member moves downwards with respect to the guide frame. Thus, the display apparatus can limit a pivoting function of a display main body as the display main body moves downwards.

### CROSS-REFERENCE TO RELATED APPLICATIONS

This application claims priority under 35 U.S.C. § 119(a) from Korean Patent Application No. 2005-0087664, filed on Sep. 21, 2005, in the Korean Intellectual Property Office, the disclosure of which is incorporated herein in its entirety by reference.

### BACKGROUND OF THE INVENTION

1. Field of the Invention

The present general inventive concept relates to a display apparatus, and more particularly, to a display apparatus having a support that provides improved rotating and lifting configurations of a display main body.

2. Description of the Related Art

Generally, a display apparatus comprises a display main body which displays an image thereon and a base member which is stably seated on an installation surface, such as a table, to support the display main body.

Recently, display main bodies have employed a thin display panel such as a liquid crystal display (LCD) panel or a plasma display panel (PDP).

Korean Patent Application No. 10-2002-0068264 discloses a monitor device as an example of a display apparatus which comprises a thin display panel. The recent conventional monitor device comprises a monitor main body, a base member which supports the monitor main body; a guide rail which stands on the base member, a slider which is coupled with the monitor main body and is coupled with the guide rail to slide, and a spring which is connected with the slider and the guide rail. Thus, the monitor main body moves upwards and downwards along the guide rail.

The conventional monitor device may comprise a pivoting function through which the monitor main body pivots around a rotating axis in forward and backward directions of the monitor device, to satisfy the needs of customers.

However, the conventional monitor device does not comprise a limiting part which limits the pivoting function of the monitor main body as the monitor main body moves downwards. Further, the limiting part should be simple to manufacture and easy to use.

### SUMMARY OF THE INVENTION

Accordingly, it is an aspect of the present general inventive concept to provide a display and display support apparatus which limits a pivoting function of a display main body as a display main body moves downwards.

Also, it is another aspect of the present general inventive concept to provide a display apparatus which rotates a display main body in various directions with respect to a base member.

Additional aspects and advantages of the present general inventive concept will be set forth in part in the description which follows and, in part, will be obvious from the description, or may be learned by practice of the general inventive concept.

The foregoing and/or other aspects of the present general inventive concept may be achieved by providing a display apparatus comprising a display main body to display an image thereon and a base member, the display apparatus further comprising a lifting unit comprising a guide frame to stand on the base member and a lifting member coupled with the guide frame to move with the display main body, a pivoting unit which is provided between the display main body and the lifting member and supports the display member to pivot around a rotating axis in clockwise and counterclockwise directions, and a locking unit comprising a moving member to move with a pivoting operation of the display main body and a locking projection provided with the guide frame to limit movement of the moving member to prevent the pivoting operation of the display main body when the lifting member moves downwards with respect to the guide frame.

The display apparatus may further comprise a moving member guide which is provided on the lifting member and supports the moving member to move in a backward direction with respect to the display main body when the display main body pivots.

The locking unit may further comprise a pressure projection which rotates together with the display main body and presses the moving member backwards when the display main body rotates.

The pressure projection may further comprise a protruding part which is shaped like a circular arc and presses the moving member when the display main body pivots, and an inclination part which is slantingly provided to an end part of the protruding part to gradually move the moving member.

A roller may be provided on an end part of the moving member to roll-contact the pressure projection.

The locking unit may comprise an elastic member which pulls the moving member toward the display main body.

The pivoting unit may comprise a pivoting bracket which is coupled with the display main body and a pivoting shaft which supports the pivoting bracket to pivot with respect to the lifting member, and wherein the pressure projection is provided on the pivoting bracket.

The lifting unit may further comprise a lifting spring which is provided between the lifting member and the guide frame to press the lifting member upwards.

The display apparatus may further comprise a swivel unit which is provided between the lifting unit and the base member and supports the display main body to swivel around a rotating axis in a lifting direction.

The swivel unit may comprise a swivel bracket which is provided on a lower part of the guide frame, a swivel supporter which protrudes from the base member, and a swivel shaft which connects the swivel bracket and the swivel supporter to swivel.

The display apparatus may further comprise a tilting unit which is provided between the lifting unit and the pivoting unit and supports the display main body to tilt around a rotating axis in up and down directions.

The tilting unit may comprise a tilting bracket which is coupled with the pivoting unit, a tilting supporter which is coupled with the lifting member, and a tilting shaft which connects the tilting bracket and the tilting supporter to tilt the display main body.

The foregoing and/or other aspects of the present general inventive concept may also be achieved by providing a supporting apparatus including a base member to support a display main body to display an image thereon, the supporting apparatus further including a lifting unit including a guide frame standing on the base member and a lifting member coupled with the guide frame to move with the display main body, and a pivoting unit which is provided between the display main body and the lifting member and supports the display member to pivot around a rotating axis in clockwise and counterclockwise directions, and a locking unit including a moving member to move with a pivoting operation of the display main body, and a locking projection provided on the guide frame to limit movement of the moving member and to prevent the pivoting operation of the display main body when the lifting member moves downwards with respect to the guide frame.

The foregoing and/or other aspects of the present general inventive concept may also be achieved by providing a display apparatus to display an image on a display supported by a base, including a display rotatably and slidably supported on the base, a support unit disposed between the display and the base to slidably support the display, including a slidable member to raise and lower the display above the base, a pivoting unit between the display and the support unit to pivot and to rotatably support the display main body, and a locking unit including a moving member to move with a rotating operation of the display, and a projection provided in the support unit to limit movement of the moving member to prevent the rotation operation of the display when the slidable member moves downwards in the support unit towards the base.

The foregoing and/or other aspects of the present general inventive concept may also be achieved by providing a support device to support a display, including a guide frame including a locking projection extending along a lengthwise direction within the guide frame, a base rotatably connected to the guide frame such that the guide frame rotates around an axis extending away from the base, a lifting member slidably connected to the guide frame to slide along a length thereof, the lifting member including a moving member extending in a direction perpendicular to a sliding direction and a tilting member to tilt with respect to the lifting member, and a pivot bracket rotatably connected to the tilting member at one side thereof and connectable to the display at another side thereof such that the display is rotatable, slidable, and tiltable with respect to the guide frame, the pivot bracket including a protrusion on the one side thereof to engage with and move the moving member into the guide frame, wherein the locking projection prevents the moving member from moving into the guide frame at predetermined positions of the lifting member with respect to the guide frame such that the display is prevented from rotating and tilting during the sliding of the lifting member in the sliding direction.

The foregoing and/or other aspects of the present general inventive concept may also be achieved by providing a method of supporting a display main body on a base, the method including rotatably supporting the display main body about a rotation axis parallel to a plane of the base to rotate the display main body about the rotation axis, and disabling the rotation of the display main body during a predetermined lengthwise movement of the display main body toward and away from the base.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 illustrates a perspective view of a display apparatus according to the present general inventive concept;

FIG. 2 illustrates an exploded perspective view of the display apparatus according to the present general inventive concept;

FIG. 3 illustrates an exploded perspective view of a tilting unit, a pivoting unit and a locking unit of the display apparatus according to the present general inventive concept;

FIG. 4 illustrates a perspective view of the tilting unit, the pivoting unit and the locking unit of the display apparatus according to the present general inventive concept when they are coupled with each other;

FIGS. 5 and 6 illustrate operational perspective views of the pivoting unit and the locking unit of the display apparatus according to the present general inventive concept;

FIG. 7 illustrates a coupling perspective view of a lifting unit of the display apparatus according to the present general inventive concept; and

FIGS. 8 and 9 illustrate operational perspective views of the lifting unit and the pivoting unit of the display apparatus according to the present general inventive concept.

### DETAILED DESCRIPTION OF THE PREFERRED EMBODIMENTS

Reference will now be made in detail to the embodiments of the present general inventive concept, examples of which are illustrated in the accompanying drawings, wherein like reference numerals refer to the like elements throughout. The embodiments are described below in order to explain the present general inventive concept by referring to the figures.

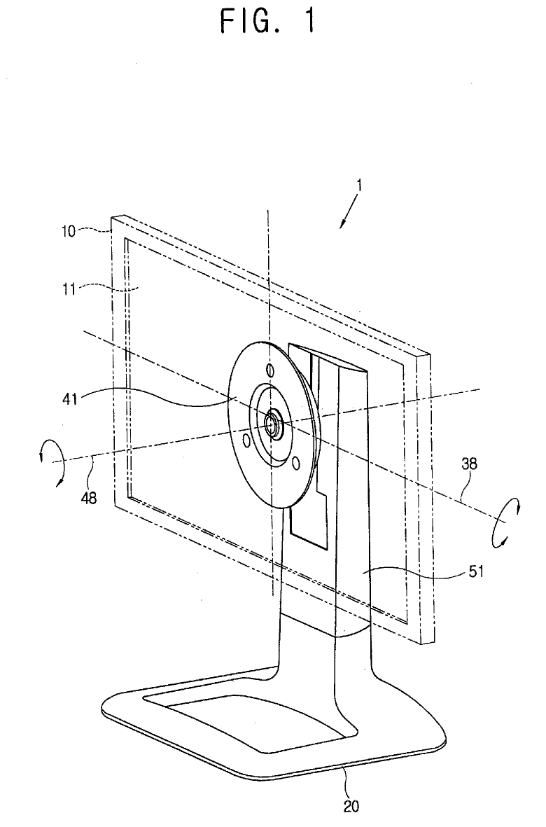

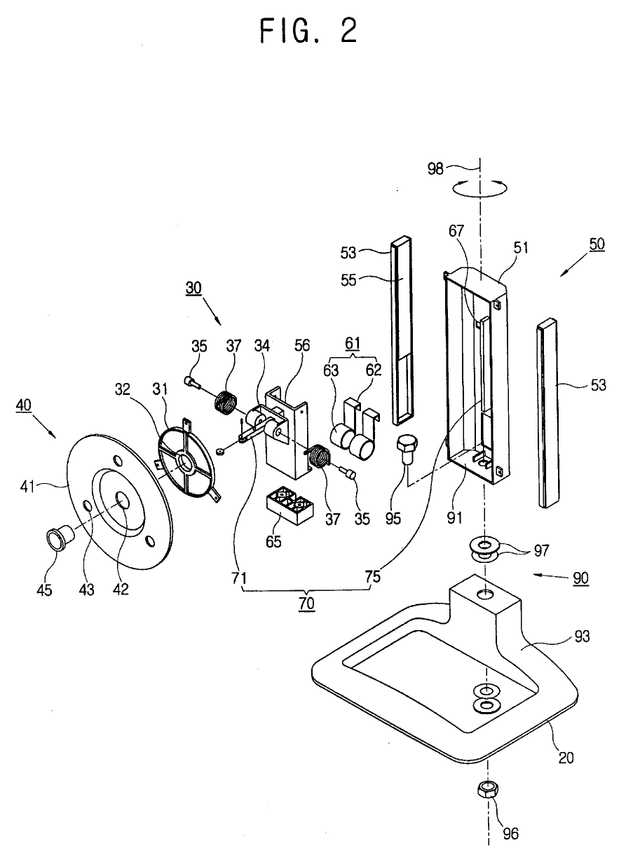

As illustrated in FIGS. 1 and 2, a display apparatus 1 according to the present general inventive concept includes a display main body 10 which displays an image thereon, a base member 20 which supports the display main body 10 with respect to an installing surface, a lifting unit 50 which is provided between the display main body 10 and the base member 20 to move the display main body 10 upwards and downwards with respect to the base member 20, a pivoting unit 40 which is provided between the display main body 10 and the lifting unit 50 and supports the display main body 10 to pivot around a rotating axis 48 in clockwise and counterclockwise directions, and a locking unit 70 which limits the display main body 10 from pivoting at the pivoting unit 40 of the display main body 10 when the display main body 10 moves downwards by way of the lifting unit 50.

Referring to FIGS. 1 and 2, the display apparatus 1 according to the present general inventive concept may further include a swivel unit 90 which is provided between the lifting unit 50 and the base member 20 and supports the display main body 10 to swivel around a rotating axis 98, and a tilting unit 30 which is provided between the pivoting unit 40 and the lifting unit 50 and supports the display main body 10 around a rotating axis 38 in up and down directions.

The display main body 10 comprises a display panel 11 having a thin plate shape such as a liquid crystal display (LCD) or a plasma display panel (PDP) to display an image thereon, and a driving circuit (not illustrated) which drives the display panel 11. A plurality of coupling holes (not illustrated) may be provided on a rear surface of the display main body 10 to be coupled with a pivoting bracket 41 (to be described later) by screws (not illustrated). The coupling holes of the display main body 10 may be formed thereon according to video electronic standard association (VESA) standards.

The base member 20 may be shaped like a plate to be installed on an installing surface such as a table, or desk, etc. The base member 20 is coupled with a guide frame 51 of the lifting unit 50 (to be described later) and supports the guide frame 51 to stand upright with respect to the installing surface.

As illustrated in FIGS. 2 through 4, the tilting unit 30 allows the display main body 10 to tilt around the rotating axis 38 in the up and down directions with respect to the lifting unit 50 and the base member 20. The tilting unit 30 comprises a tilting bracket 31 which is coupled with the pivoting unit 40, a tilting supporting part 34 which is coupled with a lifting member 56 of the lifting unit 50 (to be described later), and a tilting shaft 35 which connects the tilting bracket 31 and the tilting supporting part 34 to tilt the main body 10 and the display panel 11 up and down. The tilting unit 30 may further comprise a tilting spring 37 which is coupled with the tilting bracket 31 and the tilting supporting part 34.

Referring to FIGS. 2 through 6, tilting bracket 31 may also comprise a pivoting shaft coupler 32 which is provided on a center of a plate surface thereof to be coupled with a pivoting shaft 45 of the pivoting unit 40 (to be described later), and a tilting shaft coupler 33 which protrudes from the plate surface to the tilting supporting part 34 to be coupled with the tilting shaft 35.

The tilting supporting part 34 is coupled with the lifting member 56 of the lifting unit 50 (to be described later) to move with the lifting member 56. The tilting supporting part 34 is coupled with the tilting shaft coupler 33 of the tilting bracket 31 by the tilting shaft 35 so that the tilting bracket 31 tilts with respect to the tilting shaft 35 with a predetermined friction force.

As an example of the present general inventive concept, the tilting spring 37 may comprise a torsion coil spring, wherein a first side of the tilting spring 37 is coupled with the tilting bracket 31 and a second side thereof is coupled with the tilting supporting part 34 to press the tilting bracket 31 upwards. The elastic force of the tilting spring 37 prevents the tilting bracket 31 from tilting downwards due to the self-weight of the display main body 10.

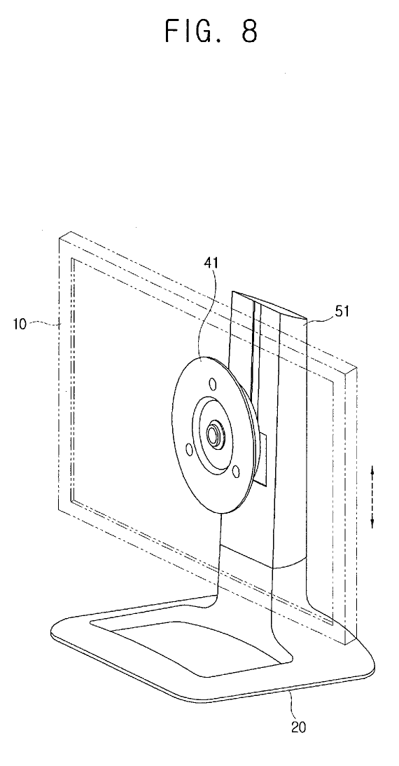

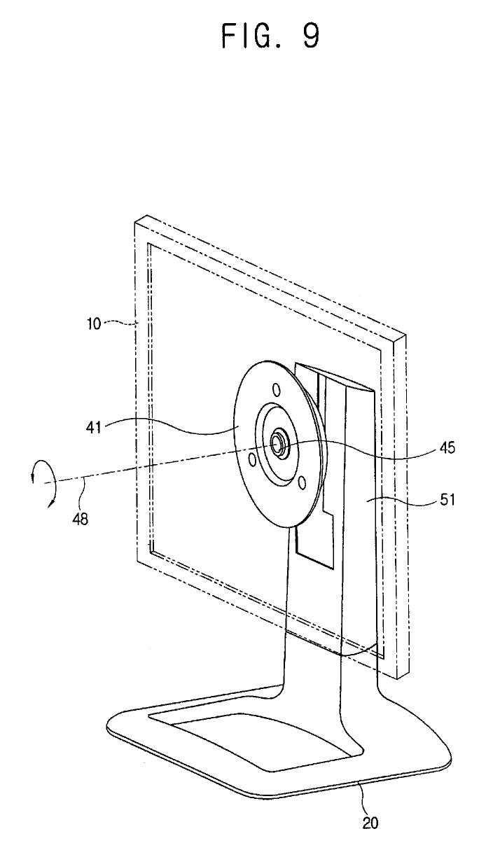

As illustrated in FIGS. 2 through 6, the pivoting unit 40 is provided between the display main body 10 and the tilting unit 30 to make the display main body 10 pivot around the rotating axis 48 in clockwise and counterclockwise directions with respect to the base member 20 within predetermined angles. The pivoting unit 40 comprises the pivoting bracket 41 which is coupled with the display main body 10; and the pivoting shaft 45 which supports the pivoting bracket 41 to pivot with respect to the lifting member 56. The predetermined angle ranges of the pivoting unit 40 may be variously set as 90° or 180°. As an example of the present general inventive concept, a pre-pivoting state refers to a state in which a long side of the display main body 10 is disposed in leftward and rightward directions (refer to FIGS. 1 and 8), and a pivoting state refers to a state in which the long side of the display main body 10 (refer to FIG. 9) is disposed in upward and downward directions.

A first end of the pivoting shaft 45 is accommodated and coupled to the pivoting shaft coupler 32 of the tilting bracket 31 and a second end thereof is coupled with a pivoting shaft accommodator 42 of the pivoting bracket 41, thereby pivoting the pivoting bracket 41 with respect to the tilting bracket 31. An end part of the pivoting shaft 45 is bent to have a predetermined rotation friction force while the pivoting shaft 45 is accommodated in the tilting shaft coupler 33 of the tilting bracket 31 and the pivoting shaft accommodator 42 of the pivoting bracket 41.

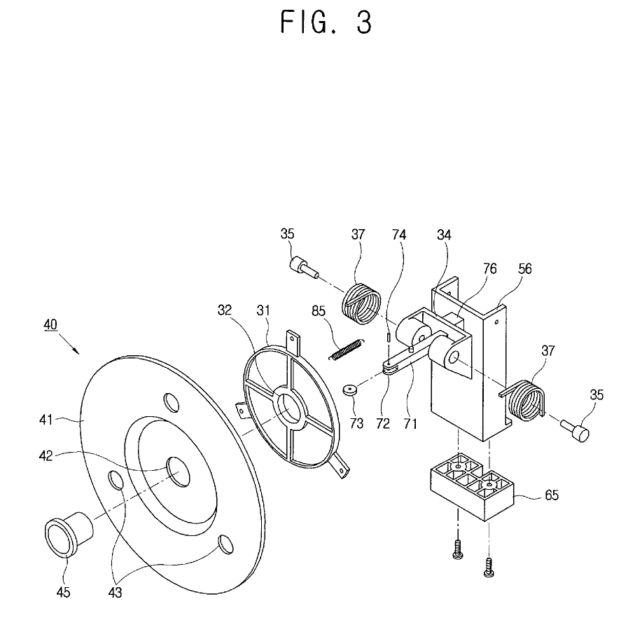

Referring to FIGS. 2 and 3, the pivoting bracket 41 is shaped like a plate. The pivoting shaft accommodator 42 is formed on a center portion of the pivoting bracket 41. The pivoting bracket 41 comprises a plurality of coupling holes 43 which are coupled with a rear part of the display main body 10 by screws (not shown).

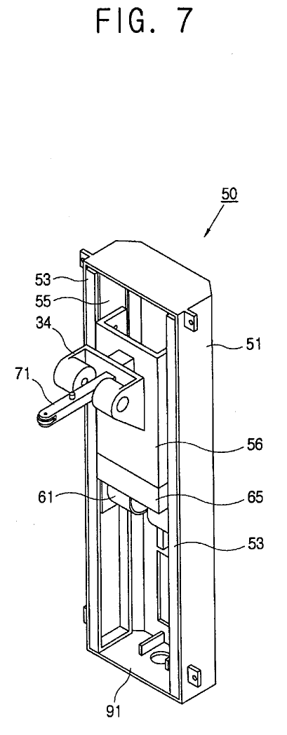

Referring to FIGS. 2 and 7, the lifting unit 50 comprises the guide frame 51, which stands on the base member 20 and the lifting member 56, which is coupled with the guide frame 51 to move with the display main body 10. The lifting unit 50 may further comprise guide rails 53 which are coupled with the guide frame 51 in a lengthwise direction, and sliders 55 which are coupled with the guide rails 53 to slide and are also coupled by screws to move with the lifting member 56. The lifting unit 50 may further comprise a lifting spring 61 which is coupled with the lifting member 56 and the guide frame 51 to press the lifting member 56 upwards.

The guide frame 51 has a box shape to support a pair of the guide rails 53 at opposite sides thereof. On a lower part of the guide frame 51 is provided a swivel bracket 91 of the swivel unit 90 (to be described later).

As an example of the present general inventive concept, the lifting spring 61 may comprise a spiral spring (see FIG. 2) which is wound like a roll, but is not limited thereto. Alternatively, the lifting spring 61 may be provided in various shapes including a coil spring. A first side 62 of the lifting spring 61 is bent to be coupled with a spring coupler 67 which is provided on an upper part of the guide frame 51, and a second side 63 thereof is wound like a roll to contact a spring supporter 65 which is provided on a lower part of the lifting member 56. Thus, the lifting spring 61 presses the lifting member 56 upwards with a predetermined elastic force. Such an elastic force of the lifting spring 61 is similar to the self-weight of the tilting unit 30, the pivoting unit 40, and the display main body 10 which are coupled with the lifting member 56. The lifting spring 61 is not limited to the spiral spring. Alternatively, the lifting spring 61 may be variously provided as a coil spring or a plate spring.

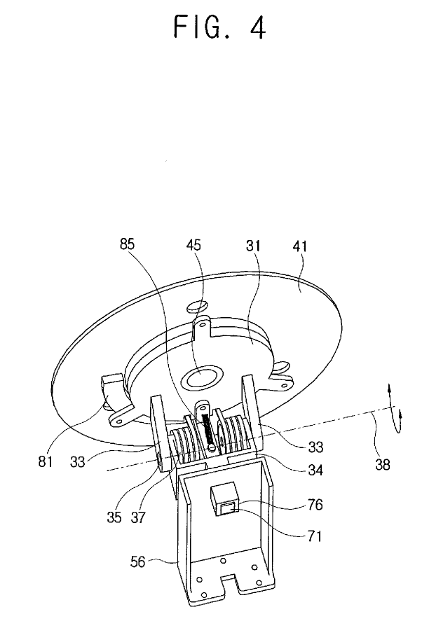

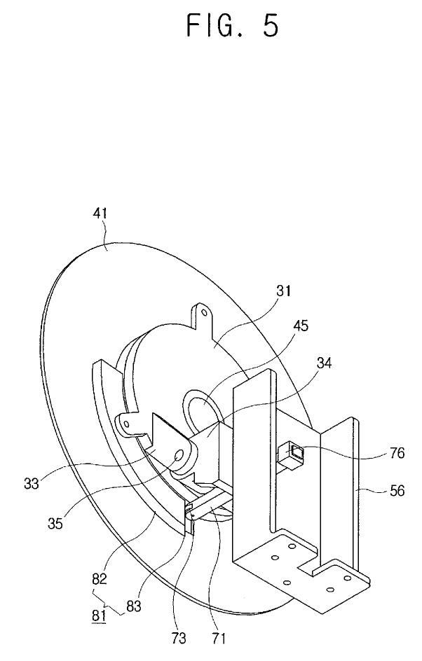

As illustrated in FIGS. 2 through 7, the locking unit 70 may comprise a moving member 71 which moves with a pivoting operation of the display main body 10, and a locking projection 75 which is provided on the guide frame 51 and limits movements of the moving member 71 to prevent the pivoting operation of the display main body 10 while the lifting member 56 moves downwards with respect to the guide frame 51. The locking unit 70 may further comprise a pressure projection 81 (see FIGS. 4 and 5) which rotates together with the display main body 10 and presses the moving member 71 backwards when the display main body 10 rotates. The locking unit 70 may further comprise an elastic member 85 which pulls the moving member 71 toward the display main body 10 by connecting one end of the elastic member 85 to the tilting bracket 31 and another end of the elastic member 85 to the moving member 71.

The moving member 71 is shaped like a bar to move with the pivoting operation of the display main body 10 and to move in forward and backward directions in relation to the display main body 10. The moving member 71 is accommodated and guided to/by a moving member guide 76 (see FIGS. 4, 5, and 6) which is provided on the lifting member 56 to be lifted up and down with the lifting member 56. A roller 73 (see FIGS. 3, 5, and 6) is provided on the moving member 71 to roll-contact the pressure projection 81.

The moving member guide 76 is formed to pass through the lifting member 56 in back and forth directions and supports the moving member 71 to move in a backward direction of the display main body 10 when the display main body 10 pivots. As an example of the present general inventive concept, the moving member guide 76 has a rectangular shape corresponding to a shape of the moving member 71, but is not limited thereto. The moving member guide 76 may be provided in various shapes including a circular or an oval shape.

Referring to FIGS. 3, 5, and 6, the roller 73 is rotatably coupled with a roller supporter 72 which is provided on a front end part of the moving member 71, by a supporting pin 74, to roll-contact a projecting surface of the pressure projection 81. Accordingly, the moving member 71 may move in the backward direction of the display main body 10 as the roller 73 roll-contacts the pressure projection 81 while the pressure projection 81 pivots together with the display main body 10.

The elastic member 85 pulls the moving member 71 toward the display main body 10 so that the roller 73 attached to the moving member 71 contacts the pressure projection 81. As an example of the present general inventive concept, the elastic member 85 may be shaped like a coil spring which is coupled the moving member 71 and the tilting bracket 31 so that the roller 73 of the moving member 71 contacts the pressure projection 81 while the display main body 10 pivots, but is not limited thereto. Alternatively, the elastic member 85 may be provided in various other forms such as a plate spring or rubber material. The moving member 71 may be coupled with the pivoting bracket 41 or with the lifting member 56 so that the elastic member 85 pulls or presses the moving member 71 toward the display main body 10.

Referring to FIG. 2, the locking projection 75 is provided on the guide frame 51 to prevent the moving member 71 from moving backwards when the lifting member 56 moves downwards by predetermined distances with respect to the guide frame 51. As an example of the present general inventive concept, the locking projection 75 protrudes forward in a horizontal direction of the guide frame 51 and extends along an inside of the box shaped guide frame 51 in a vertical direction. Thus, the locking projection 75 prevents the moving member 71 from moving backward when the lifting member 56 moves vertically downward by predetermined distances with respect to the guide frame 51 and contacts a rear end part of the moving member 71. For example, the predetermined distances can be distances where the lifting member 56 moves in a vertical direction by the predetermined distances corresponding to a state when the display main body 10 contacts the base member 20 or the installing surface while pivoting.

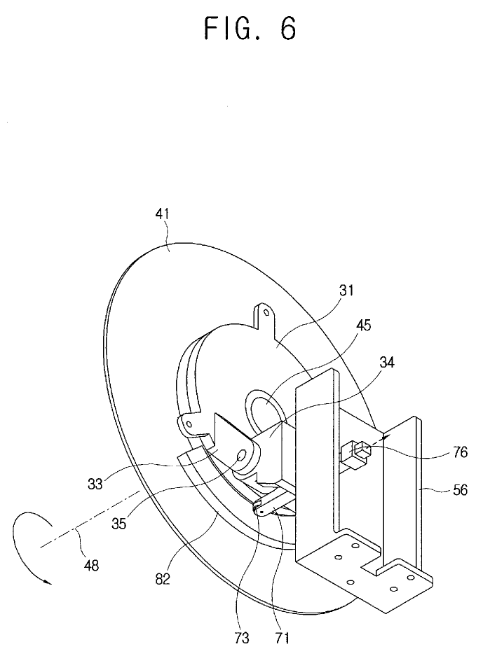

As illustrated in FIGS. 5 and 6, the pressure projection 81 comprises a protruding part 82 which is shaped like a circular arc to press the moving member 71 when the display main body 10 pivots, and an inclination part 83 (see FIG. 5) which is provided slantingly to an end part of the protruding part 82 to gradually move the moving member 71. As an example of the present general inventive concept, the pressure projection 81 may be provided on the pivoting bracket 41, but is not limited thereto. Alternatively, the pressure projection 81 may be provided on a rear surface of the display main body 10.

FIGS. 5 and 6 illustrate that the protruding part 82 protrudes in a backward direction of the pivoting bracket 41 to contact the moving member 71. The protruding part 82 is shaped like a circular arc and surrounds the pivoting shaft accommodator 42 (see FIGS. 2 and 3) of the pivoting bracket 41. Thus, the protruding part 82 pivots together with the pivoting bracket 41 and the display main body 10 and presses the moving member 71, which is coupled with the lifting member 56 via the moving member guide 76, to move forward and backward.

The inclination part 83 is provided on an end part of the protruding part 82 to gradually guide the roller 73 of the moving member 71 toward the protruding part 82. Thus, the roller 73 of the moving member 71 roll-contacts the inclination part 83 of the protruding part 82 to move backward when the display main body 10 pivots around rotation axis 38 or rotation axis 48.

As illustrated in FIGS. 2, 5 and 6, the display main body 10 presses the moving member 71 by way of the pressure projection 81 to move the moving member 71 backward while pivoting around the pivoting shaft 45. As the moving member 71 is prevented from moving backwards by the locking projection 75 while the lifting member 56 moves downward by predetermined distances with respect to the guide frame 51, the pressure projection 81 is prevented from pivoting by the moving member 71, and then the display main body 10 can not pivot either.

As illustrated in FIGS. 1 and 2, the swivel unit 90 allows the display main body 10 to swivel around the rotating axis 98 in a lifting direction of the display main body 10 with respect to the base member 20. The swivel unit 90 comprises the swivel bracket 91 which is provided on a lower part of the guide frame 51, a swivel supporter 93 which protrudes upwards from the base member 20, and a swivel shaft 95 which connects the swivel bracket 91 and the swivel supporter 93 to swivel around the rotation axis 98. The swivel unit 90 may further comprise at least one washer 97 which is provided between the swivel bracket 91 and the swivel supporter 93.

As an example of the present general inventive concept, referring to FIG. 2, the swivel shaft 95 is shaped like a bolt to be accommodated by the swivel bracket 91 and the swivel supporter 93 and to be coupled with a coupling nut 96. Thus, the swivel bracket 91 can have a predetermined rotation friction force with respect to the swivel supporter 93. A user may swivel the display main body 10 (illustrated in FIGS. 1 and 9) with respect to the base member 20 by overcoming such a predetermined rotation friction force.

With this configuration, a process of operating the display apparatus 1 according to the present general inventive concept will be described.

As illustrated in FIGS. 1, 2, and 9, the display main body 10 may pivot around the pivoting shaft 45 when the display main body 10 moves to an upper part of the guide frame 51 of the lifting unit 50 (i.e., the display main body is in a pivoting state). Then, the moving member 71 is not interfered with by the locking projection 75 (illustrated in FIG. 2) even if the moving member 71 moves backward by the pressure projection 81 when the display main body 10 pivots (refer to FIGS. 5 through 7). This is because the moving member 71 reaches an end of the locking projection 75 in a vertical direction of the guide frame 51.

As illustrated in FIG. 8, the display main body 10 hardly pivots around the pivoting shaft 45 when the display main body 10 moves downward by predetermined distances from the upper part of the guide frame 51 of the lifting unit 50. The moving member 71 cannot move backward due to interference by the locking projection 75 when moving backward due to contact with the pressure projection 81 while the display main body 10 pivots. Accordingly, the display main body 10 cannot pivot and is in a pre-pivoting state (refer to FIGS. 5, 6, and 7).

The display apparatus according to the present general inventive concept limits the pivoting operation of the display main body by providing the locking unit when the display main body moves downward by predetermined distances with respect to the length of the guide frame, thereby preventing the display main body from contacting the base member or the installing surface when the display main body pivots.

The locking unit may limit the pivoting operation of the display main body by providing the moving member moving with the display main body and the locking projection limiting the movement of the moving member.

As illustrated in FIGS. 1 and 2, the display main body 10 of the display apparatus 1 according to the present general inventive concept may tilt around a rotating axis 38 in up and down directions, may pivot around a rotating axis 48 in clockwise and counterclockwise directions, and may swivel around the rotating axis 98.

Thus, the display apparatus according to the present general inventive concept may pivot, tilt, and swivel the display main body with respect to a base member, thereby providing various viewing angles to a user. Although the display apparatus according to the present general inventive concept has been illustrated and described as being in relation to a horizontal surface such as a table or desk, the present general inventive concept is not limited thereto and could apply to support at a vertical surface such as a wall.

Although a few embodiments of the present general inventive concept have been illustrated and described, it will be appreciated by those skilled in the art that changes may be made in these embodiments without departing from the principles and spirit of the general inventive concept, the scope of which is defined in the appended claims and their equivalents.

What is claimed is:

1. A display apparatus comprising a display main body to display an image thereon and a base member, the display apparatus further comprising:
a lifting unit comprising:
a guide frame to stand on the base member, and
a lifting member coupled with the guide frame to move with the display main body;
a pivoting unit which is provided between the display main body and the lifting member and supports the display member to pivot around a rotating axis in clockwise and counterclockwise directions; and
a locking unit comprising:
a moving member to move with a pivoting operation of the display main body, and
a locking projection provided with the guide frame to limit movement of the moving member to prevent the pivoting operation of the display main body when the lifting member moves downward with respect to the guide frame.

2. The display apparatus according to claim 1, further comprising:
a moving member guide which is provided on the lifting member and supports the moving member to move in a backward direction with respect to the display main body when the display main body pivots.

3. The display apparatus according to claim 2, wherein the locking unit further comprises:
a pressure projection which rotates together with the display main body and presses the moving member backward when the display main body rotates.

4. The display apparatus according to claim 3, wherein the pressure projection comprises:
a protruding part which is shaped like a circular arc and presses the moving member when the display main body pivots; and
an inclination part which is slantingly provided at an end part of the protruding part to gradually move the moving member.

5. The display apparatus according to claim 4, wherein a roller is provided on the end part of the moving member to roll-contact the pressure projection.

6. The display apparatus according to claim 2, wherein the locking unit comprises:
an elastic member which pulls the moving member toward the display main body.

7. The display apparatus according to claim 3, wherein the pivoting unit comprises:
a pivoting bracket which is coupled with the display main body; and
a pivoting shaft which supports the pivoting bracket to pivot with respect to the lifting member,
wherein the pressure projection is provided on the pivoting bracket.

8. The display apparatus according to claim 4, wherein the pivoting unit comprises:
a pivoting bracket which is coupled with the display main body; and
a pivoting shaft which supports the pivoting bracket to pivot with respect to the lifting member,
wherein the pressure projection is provided on the pivoting bracket.

9. The display apparatus according to claim 1, wherein the lifting unit further comprises:
a lifting spring which is provided between the lifting member and the guide frame to press the lifting member upwards.

10. The display apparatus according to claim 1, further comprising:
a swivel unit which is provided between the lifting unit and the base member and supports the display main body to swivel around a rotating axis in a lifting direction.

11. The display apparatus according to claim 10, wherein the swivel unit comprises:
a swivel bracket which is provided on a lower part of the guide frame;
a swivel supporter which protrudes from the base member; and
a swivel shaft which connects the swivel bracket and the swivel supporter to swivel.

12. The display apparatus according to claim 1, further comprising:
a tilting unit which is provided between the lifting unit and the pivoting unit and supports the display main body to tilt around a rotating axis in up and down directions.

13. The display apparatus according to claim 12, wherein the tilting unit comprises:
a tilting bracket which is coupled with the pivoting unit;
a tilting supporter which is coupled with the lifting member; and
a tilting shaft which connects the tilting bracket and the tilting supporter to tilt the display main body.

14. A supporting apparatus comprising a base member to support a display main body to display an image thereon, the supporting apparatus further comprising:
a lifting unit comprising:
a guide frame standing on the base member and a lifting member coupled with the guide frame to move with the display main body, and
a pivoting unit which is provided between the display main body and the lifting member and supports the display member to pivot around a rotating axis in clockwise and counterclockwise directions; and
a locking unit comprising:
a moving member to move with a pivoting operation of the display main body, and
a locking projection provided on the guide frame to limit movement of the moving member and to prevent the pivoting operation of the display main body when the lifting member moves downwards with respect to the guide frame.

15. The supporting apparatus according to claim 14, the supporting apparatus further comprising:
a moving member guide which is provided on the lifting member and supports the moving member to move in a backward direction with respect to the display main body when the display main body pivots.

16. The supporting apparatus according to claim 15, wherein the locking unit further comprises:
a pressure projection which rotates together with the display main body and presses the moving member backward when the display main body rotates.

17. The supporting apparatus according to claim 16, wherein the pressure projection comprises:
a protruding part which is shaped like a circular arc and presses the moving member when the display main body pivots; and
an inclination part which is slantingly provided at an end part of the protruding part to gradually move the moving member.

18. The supporting apparatus according to claim 17, wherein a roller is provided on an end part of the moving member to roll-contact the pressure projection.

19. The supporting apparatus according to claim 15, wherein the locking unit comprises:
an elastic member which pulls the moving member toward the display main body.

20. The supporting apparatus according to claim 16, wherein the pivoting unit comprises:
a pivoting bracket which is coupled with the display main body; and
a pivoting shaft which supports the pivoting bracket to pivot with respect to the lifting member,
wherein the pressure projection is provided on the pivoting bracket.

21. The supporting apparatus according to claim 17, wherein the pivoting unit comprises:
a pivoting bracket which is coupled with the display main body; and
a pivoting shaft which supports the pivoting bracket to pivot with respect to the lifting member,
wherein the pressure projection is provided on the pivoting bracket.

22. The supporting apparatus according to claim 14, wherein the lifting unit further comprises:
a lifting spring which is provided between the lifting member and the guide frame to press the lifting member upwards.

23. The supporting apparatus according to claim 14, further comprising:
a swivel unit which is provided between the lifting unit and the base member and supports the display main body to swivel around a rotating axis in a lifting direction.

24. The supporting apparatus according to claim 23, wherein the swivel unit comprises:
a swivel bracket which is provided on a lower part of the guide frame;
a swivel supporter which protrudes from the base member; and
a swivel shaft which connects the swivel bracket and the swivel supporter to swivel.

25. The supporting apparatus according to claim 14, further comprising:
a tilting unit which is provided between the lifting unit and the pivoting unit and supports the display main body to tilt around a rotating axis in up and down directions.

26. The supporting apparatus according to claim 25, wherein the tilting unit comprises:
a tilting bracket which is coupled with the pivoting unit;
a tilting supporter which is coupled with the lifting member; and
a tilting shaft which connects the tilting bracket and the tilting supporter to tilt the display main body.

27. A display apparatus to display an image on a display supported by a base, comprising:
a display rotatably and slidably supported by the base;
a support unit disposed between the display and the base to slidably support the display with respect to the base, comprising a slidable member to raise and lower the display with respect to the base;
a pivoting unit disposed between the display and the support unit to pivot and to rotate the display with respect to the support unit; and
a locking unit comprising:
a moving member to move with a rotating operation of the display, and
a projection provided in the support unit to limit movement of the moving member to prevent the rotation operation of the display when the slidable member moves downward in the support unit towards the base.

28. A support device to support a display, comprising:
a guide frame including a locking projection extending along a lengthwise direction within the guide frame;
a base rotatably connected to the guide frame such that the guide frame rotates around an axis extending away from the base;
a lifting member slidably connected to the guide frame to slide along a length thereof, the lifting member including a moving member extending in a direction perpendicular to a sliding direction and a tilting member to tilt with respect to the lifting member; and
a pivot bracket rotatably connected to the tilting member at one side thereof and connectable to the display at another side thereof such that the display is rotatable, slidable, and tiltable with respect to the guide frame, the pivot bracket including a protrusion on the one side thereof to engage with and move the moving member into the guide frame,
wherein the locking projection prevents the moving member from moving into the guide frame at predetermined positions of the lifting member with respect to the guide frame such that the display is prevented from rotating and tilting during the sliding of the lifting member in the sliding direction.

29. The support device of claim 28, wherein the moving member further comprises a roller at one end thereof to provide a rolling contact with the protrusion of the pivot bracket.

30. The support device of claim 29, wherein the protrusion of the pivot bracket comprises a gradual incline at an end thereof.

31. The support device of claim 30, wherein the lifting member further comprises:
a moving member guide to slidably receive the moving member in the direction perpendicular to the sliding direction of the lifting member.

32. A method of supporting a display main body on a base, the method comprising:
rotatably supporting the display main body about a rotation axis parallel to a plane of the base to rotate the display main body about the rotation axis; and
disabling the rotation of the display main body during a predetermined lengthwise movement of the display main body toward and away from the base.

33. The support method of claim 32, wherein the rotatably supporting of the display main body further comprises:
rotatably supporting the display main body on a lifting unit about a swivel axis perpendicular to the plane of the base member to swivel the display main body about the swivel axis.

34. The support method of claim 33, wherein the rotatably supporting the display main body further comprises:
rotatably supporting the display main body about a tilting axis perpendicular to the swivel axis and the rotation axis to tilt the display main body about the tilting axis.

35. The support method of claim 34, wherein the disabling of the rotation of the display main body further comprises:
disabling the tilting of the display main body.
